(19) United States
(12) Patent Application Publication
(10) Pub. No.: US 2012/0241833 A1
(43) Pub. Date: Sep. 27, 2012

(54) NONVOLATILE SEMICONDUCTOR STORAGE DEVICE AND METHOD FOR MANUFACTURING THE SAME

(75) Inventor: Hidenobu NAGASHIMA, Mie (JP)

(73) Assignee: Kabushiki Kaisha Toshiba, Tokyo (JP)

(21) Appl. No.: 13/422,262

(22) Filed: Mar. 16, 2012

(30) Foreign Application Priority Data
Mar. 24, 2011 (JP) 2011-066558

(51) Int. Cl. H01L 29/788; H01L 21/762

(52) U.S. Cl. 257/315; 438/424; 257/E29.3; 257/E21.546; 257/E21.422

(57) ABSTRACT

According to one embodiment, the storage device further includes: a first electrode that is formed in a reverse convex and in contact with an upper surface of a first region, parts of a side and an upper surface of a first isolation region that face a second isolation region, and parts of a side and an upper surface of the second isolation region that face the first isolation region; and a third electrode that is positioned in a different direction from a second direction with respect to the first electrode, formed in a reverse convex and in contact with an upper surface of a second region, parts of a side and the upper surface of the second isolation region that face a third isolation region, and parts of a side and an upper surface of the third isolation region that face the second isolation region.

### CROSS-REFERENCE TO RELATED APPLICATIONS

This application is based upon and claims the benefit of priority from Japanese Patent Application No. 2011-66558, filed on Mar. 24, 2011; the entire contents of which are incorporated herein by reference.

### FIELD

An embodiment described herein generally relates to a nonvolatile semiconductor storage device and a method for manufacturing the same.

### BACKGROUND

In development of a semiconductor storage device, the miniaturization of elements to achieve a large capacity and low cost has been advanced year by year. For example, in an NAND flash memory device, the miniaturization of wiring pitches such as a bit line and a word line is advanced. When the wiring pitches are miniaturized, it is difficult to open, at high aspect, a contact hole miniaturized to the same extent as a line wiring, and therefore there is proposed a “staggered arrangement” in which arrangements of bit line contacts and source line contacts are alternately shifted in the bit line direction.

However, in the case of producing a semiconductor storage device having such a configuration, when processing of opening a bit-line contact hole pattern is performed, a resist is opened by a lithography technique and processed by a reactive ion etching (hereinafter referred to as “RIE”) method. At that time, when misalignment occurs in the lithography or processing in the RIE method has variations, the distance between the bit line contact and its adjacent element region becomes short. Thus, if the adjacent distance becomes short, there arises a problem that breakdown is caused when an operating voltage is applied.

### BRIEF DESCRIPTION OF THE DRAWINGS

FIG. 1 is a cross-sectional view of one process of a manufacture method for a nonvolatile semiconductor storage device according to an embodiment.

FIG. 2 is a cross-sectional view of one process of a manufacture method for a nonvolatile semiconductor storage device according to an embodiment.

FIG. 3 is a cross-sectional view of one process of a manufacture method for a nonvolatile semiconductor storage device according to an embodiment.

FIG. 4 is a cross-sectional view of one process of a manufacture method for a nonvolatile semiconductor storage device according to an embodiment.

FIG. 5 is a cross-sectional view of one process of a manufacture method for a nonvolatile semiconductor storage device according to an embodiment.

FIG. 6A is a top view of one process of a manufacture method for a nonvolatile semiconductor storage device according to an embodiment.

FIGS. 6B to 6F are cross-sectional views of one process of a manufacture method for a nonvolatile semiconductor storage device according to an embodiment, where FIG. 6B is a cross-sectional view in the A-A′-direction of FIG. 6A, FIG. 6C is a cross-sectional view in the B-B′-direction of FIG. 6A, FIG. 6D is a cross-sectional view in the C-C′-direction of FIG. 6A, FIG. 6E is a cross-sectional view in the D-D′-direction of FIG. 6A, and FIG. 6F is a cross-sectional view in the E-E′-direction of FIG. 6A.

FIG. 7A is a top view of one process of a manufacture method for a nonvolatile semiconductor storage device according to an embodiment.

FIGS. 7B to 7F are cross-sectional views of one process of a manufacture method for a nonvolatile semiconductor storage device according to an embodiment, where FIG. 7B is a cross-sectional view in the A-A′-direction of FIG. 7A, FIG. 7C is a cross-sectional view in the B-B′-direction of FIG. 7A, FIG. 7D is a cross-sectional view in the C-C′-direction of FIG. 7A, FIG. 7E is a cross-sectional view in the D-D′-direction of FIG. 7A, and FIG. 7F is a cross-sectional view in the E-E′-direction of FIG. 7A.

FIG. 8A is a top view of one process of a manufacture method for a nonvolatile semiconductor storage device according to an embodiment.

FIGS. 8B to 8F are cross-sectional views of one process of a manufacture method for a nonvolatile semiconductor storage device according to an embodiment, where FIG. 8B is a cross-sectional view in the A-A′-direction of FIG. 8A, FIG. 8C is a cross-sectional view in the B-B′-direction of FIG. 8A, FIG. 8D is a cross-sectional view in the C-C′-direction of FIG. 8A, FIG. 8E is a cross-sectional view in the D-D′-direction of FIG. 8A, and FIG. 8F is a cross-sectional view in the E-E′-direction of FIG. 8A.

FIG. 9A is a top view of one process of a manufacture method for a nonvolatile semiconductor storage device according to an embodiment.

FIGS. 9B to 9F are cross-sectional views of one process of a manufacture method for a nonvolatile semiconductor storage device according to an embodiment, where FIG. 9B is a cross-sectional view in the A-A′-direction of FIG. 9A, FIG. 9C is a cross-sectional view in the B-B′-direction of FIG. 9A, FIG. 9D is a cross-sectional view in the C-C′-direction of FIG. 9A, FIG. 9E is a cross-sectional view in the D-D′-direction of FIG. 9A, and FIG. 9F is a cross-sectional view in the E-E′-direction of FIG. 9A.

FIG. 10A is a top view of one process of a manufacture method for a nonvolatile semiconductor storage device according to an embodiment.

FIGS. 10B to 10F are cross-sectional views of one process of a manufacture method for a nonvolatile semiconductor storage device according to an embodiment, where FIG. 10B is a cross-sectional view in the A-A′-direction of FIG. 10A, FIG. 10C is a cross-sectional view in the B-B′-direction of FIG. 10A, FIG. 10D is a cross-sectional view in the C-C′-direction of FIG. 10A, FIG. 10E is a cross-sectional view in the D-D′-direction of FIG. 10A, and FIG. 10F is a cross-sectional view in the E-E′-direction of FIG. 10A.

FIG. 11A is a top view of one process of a manufacture method for a nonvolatile semiconductor storage device according to an embodiment.

FIGS. 11B to 11F are cross-sectional views of one process of a manufacture method for a nonvolatile semiconductor storage device according to an embodiment, where FIG. 11B is a cross-sectional view in the A-A′-direction of FIG. 11A, FIG. 11C is a cross-sectional view in the B-B′-direction of FIG. 11A, FIG. 11D is a cross-sectional view in the C-C′-direction of FIG. 11A, FIG. 11E is a cross-sectional view in the D-D′-direction of FIG. 11A, and FIG. 11F is a cross-sectional view in the E-E′-direction of FIG. 11A.

FIG. 12A is a top view of one process of a manufacture method for a nonvolatile semiconductor storage device according to an embodiment.

FIGS. 12B to 12F are cross-sectional views of one process of a manufacture method for a nonvolatile semiconductor storage device according to an embodiment, where FIG. 12B is a cross-sectional view in the A-A′-direction of FIG. 12A, FIG. 12C is a cross-sectional view in the B-B′-direction of FIG. 12A, FIG. 12D is a cross-sectional view in the C-C′-direction of FIG. 12A, FIG. 12E is a cross-sectional view in the D-D′-direction of FIG. 12A, and FIG. 12F is a cross-sectional view in the E-E′-direction of FIG. 12A.

FIG. 13A is a top view of one process of a manufacture method for a nonvolatile semiconductor storage device according to an embodiment.

FIGS. 13B to 13F are cross-sectional views of one process of a manufacture method for a nonvolatile semiconductor storage device according to an embodiment, where FIG. 13B is a cross-sectional view in the A-A′-direction of FIG. 13A, FIG. 13C is a cross-sectional view in the B-B′-direction of FIG. 13A, FIG. 13D is a cross-sectional view in the C-C′-direction of FIG. 13A, FIG. 13E is a cross-sectional view in the D-D′-direction of FIG. 13A, and FIG. 13F is a cross-sectional view in the E-E′-direction of FIG. 13A.

FIG. 14A is a top view of one process of a manufacture method for a nonvolatile semiconductor storage device according to an embodiment.

FIGS. 14B to 14F are cross-sectional views of one process of a manufacture method for a nonvolatile semiconductor storage device according to an embodiment, where FIG. 14B is a cross-sectional view in the A-A′-direction of FIG. 14A, FIG. 14C is a cross-sectional view in the B-B′-direction of FIG. 14A, FIG. 14D is a cross-sectional view in the C-C′-direction of FIG. 14A, FIG. 14E is a cross-sectional view in the D-D′-direction of FIG. 14A, and FIG. 14F is a cross-sectional view in the E-E′-direction of FIG. 14A.

FIG. 15A is a top view of one process of a manufacture method for a nonvolatile semiconductor storage device according to an embodiment.

FIGS. 15B to 15F are cross-sectional views of one process of a manufacture method for a nonvolatile semiconductor storage device according to an embodiment, where FIG. 15B is a cross-sectional view in the A-A′-direction of FIG. 15A, FIG. 15C is a cross-sectional view in the B-B′-direction of FIG. 15A, FIG. 15D is a cross-sectional view in the C-C′-direction of FIG. 15A, FIG. 15E is a cross-sectional view in the D-D′-direction of FIG. 15A, and FIG. 15F is a cross-sectional view in the E-E′-direction of FIG. 15A.

FIG. 16A is a top view of one process of a manufacture method for a nonvolatile semiconductor storage device according to an embodiment.

FIGS. 16B to 16F are cross-sectional views of one process of a manufacture method for a nonvolatile semiconductor storage device according to an embodiment, where FIG. 16B is a cross-sectional view in the A-A′-direction of FIG. 16A, FIG. 16C is a cross-sectional view in the B-B′-direction of FIG. 16A, FIG. 16D is a cross-sectional view in the C-C′-direction of FIG. 16A, FIG. 16E is a cross-sectional view in the D-D′-direction of FIG. 16A, and FIG. 16F is a cross-sectional view in the E-E′-direction of FIG. 16A.

FIG. 17A is a top view of one process of a manufacture method for a nonvolatile semiconductor storage device according to an embodiment.

FIGS. 17B to 17F are cross-sectional views of one process of a manufacture method for a nonvolatile semiconductor storage device according to an embodiment, where FIG. 17B is a cross-sectional view in the A-A′-direction of FIG. 17A, FIG. 17C is a cross-sectional view in the B-B′-direction of FIG. 17A, FIG. 17D is a cross-sectional view in the C-C′-direction of FIG. 17A, FIG. 17E is a cross-sectional view in the D-D′-direction of FIG. 17A, and FIG. 17F is a cross-sectional view in the E-E′-direction of FIG. 17A.

FIG. 18A is a top view of one process of a manufacture method for a nonvolatile semiconductor storage device according to an embodiment.

FIGS. 18B to 18F are cross-sectional views of one process of a manufacture method for a nonvolatile semiconductor storage device according to an embodiment, where FIG. 18B is a cross-sectional view in the A-A′-direction of FIG. 18A, FIG. 18C is a cross-sectional view in the B-B′-direction of FIG. 18A, FIG. 18D is a cross-sectional view in the C-C′-direction of FIG. 18A, FIG. 18E is a cross-sectional view in the D-D′-direction of FIG. 18A, and FIG. 18F is a cross-sectional view in the E-E′-direction of FIG. 18A.

### DETAILED DESCRIPTION

According to one embodiment, a nonvolatile semiconductor storage device includes: a first element isolation region, a second element isolation region, a third element isolation region and a fourth element isolation region that are formed on a semiconductor substrate, extended in a first direction, separated in parallel and have a same upper surface height; a first element region that is sandwiched between the first element isolation region and the second element isolation region in a second direction perpendicular to the first direction and has an upper surface located in a lower position than an upper surface of the first element isolation region and an upper surface of the second element isolation region; a second element region that is sandwiched between the second element isolation region and the third element isolation region in the second direction and has a same upper surface height as the first element region; and a third element region that is sandwiched between the third element isolation region and the fourth element isolation region in the second direction and has a same upper surface height as the first element region. According to one embodiment, the nonvolatile semiconductor storage device further includes: a first bit line contact electrode that is formed in a reverse convex shape and in contact with an upper surface of the first element region, parts of a side surface and the upper surface of the first element isolation region that are positioned higher than the upper surface of the first element region and face the second element isolation region, and parts of a side surface and the upper surface of the second element isolation region that are positioned higher than the upper surface of the first element region and face the first element isolation region; a second bit line contact electrode that is positioned in the second direction with respect to the first bit line contact electrode, formed in a reverse convex shape and in contact with an upper surface of the third element region, parts of a side surface and an upper surface of the third element isolation region that are positioned higher than the upper surface of the third element region and face the fourth element isolation region, and parts of a side surface and an upper surface of the fourth element isolation region that are positioned higher than the upper surface of the third element region and face the third element isolation region; and a third bit line contact electrode that is positioned in a different direction from the second direction with respect to the first bit line contact electrode, formed in a reverse convex shape and in contact with an upper surface of the second element region, parts of a side surface and the upper surface of the second element isolation region that are positioned higher than the upper surface of the second element region and face the third element isolation region, and parts of a side surface and the upper surface of the third element isolation region that are positioned higher than the upper surface of the second element region and face the second element isolation region.

The nonvolatile semiconductor storage device and a manufacture method therefor will be explained below in detail with reference to the accompanying drawings. The present invention is not limited to the following embodiment.

### Embodiment

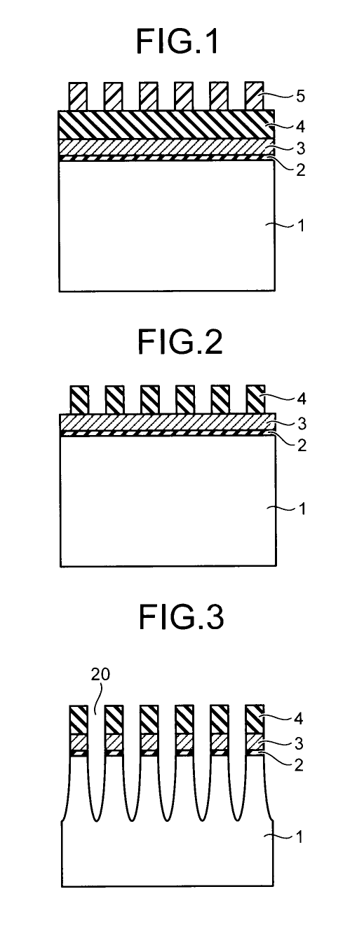

A manufacture method for a nonvolatile semiconductor storage device having a memory cell transistor according to an embodiment of the present invention is shown in FIGS. 1 to 18F.

First, as shown in FIG. 1, on a semiconductor substrate 1, a tunnel insulating film 2, a P-doped polycrystalline Si film as a floating gate 3, an SiN film 4 as a mask of reactive ion etching (“RIE”) are formed by a chemical vapor deposition (“CVD”) method and further a photoresist film 5 is applied. At this time, the SiN film 4 may be a SiO₂ film. Next, by a normal lithography technique, the photoresist film 5 is subjected to patterning in an element region shape (FIG. 1). Also, FIGS. 1 to 5 are cross-sectional views where the paper perpendicular direction is a bit line direction.

Next, as shown in FIG. 2, the SiN film 4 is processed by RIE using the photoresist film 5 as a mask to form a hardmask on the element region. The photoresist film 5 is removed by ashing processing or the like.

After that, as shown in FIG. 3, by RIE using the SiN film 4 as a hardmask, the P-doped polycrystalline Si film 3, the tunnel insulating film 2 and the semiconductor substrate 1 are processed in order. As above, a trench 20 for shallow trench isolation (“STI”) is formed.

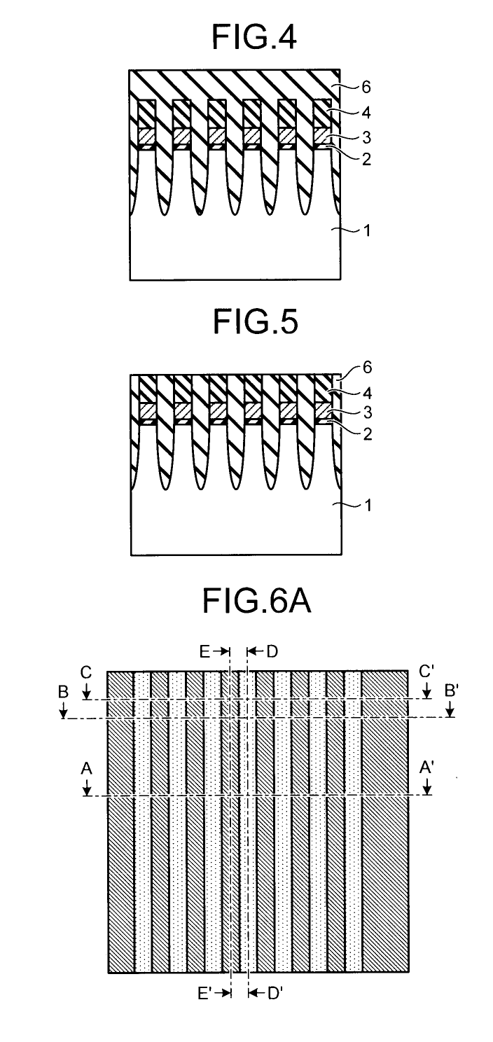

After that, as shown in FIG. 4, an SiO₂ film as an element isolation film 6 is embedded to the STI by a CVD method or a coating method. Next, as shown in FIG. 5, the element isolation film 6 is polished by chemical mechanical polishing (“CMP”) and the SiN film 4 is planarized as a stopper film.

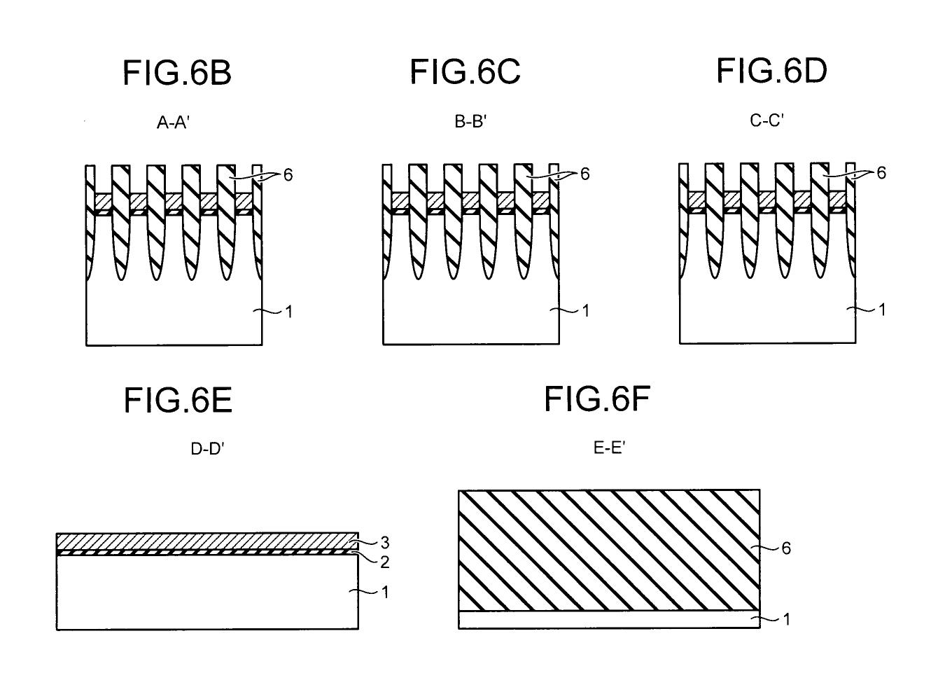

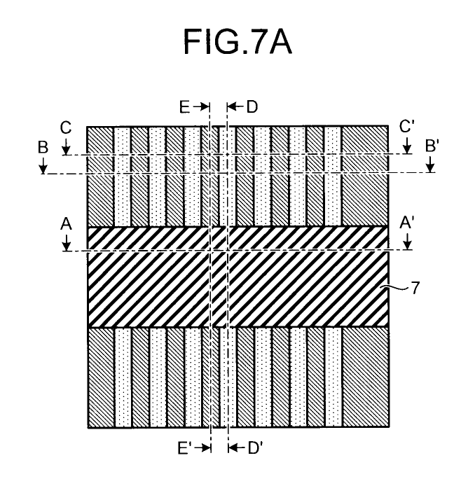

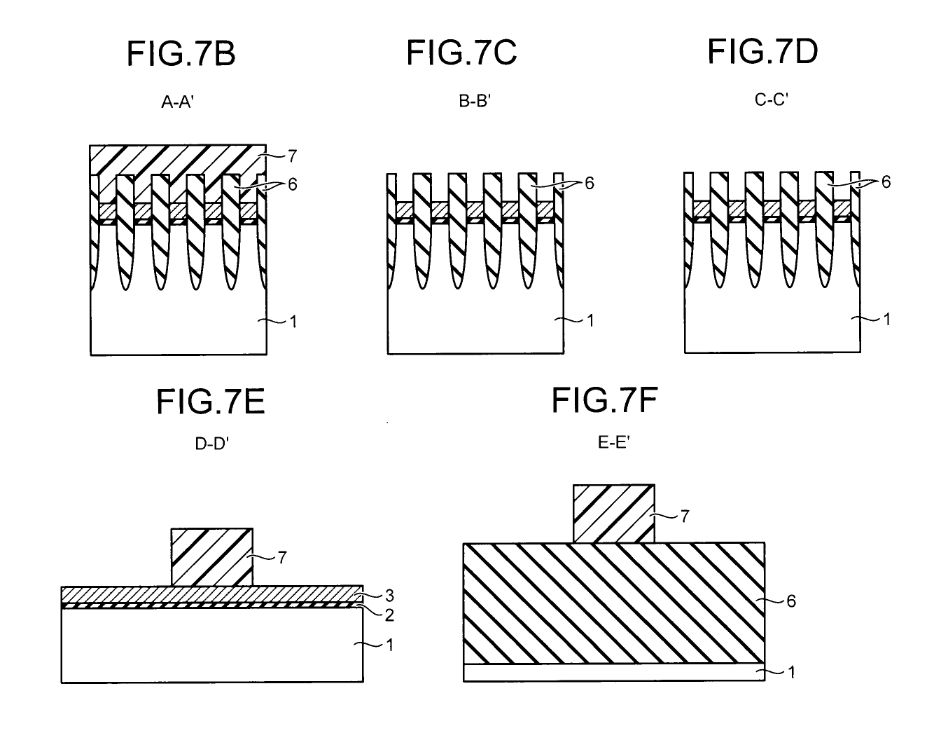

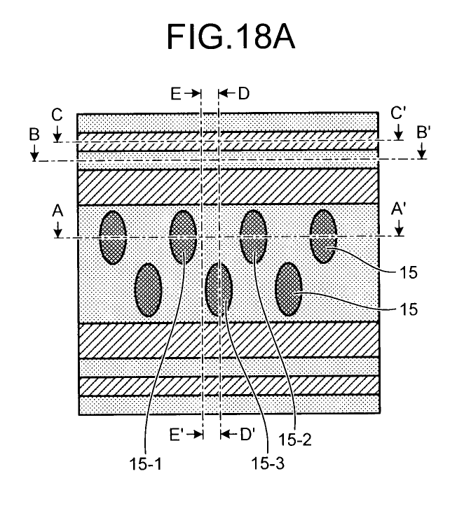

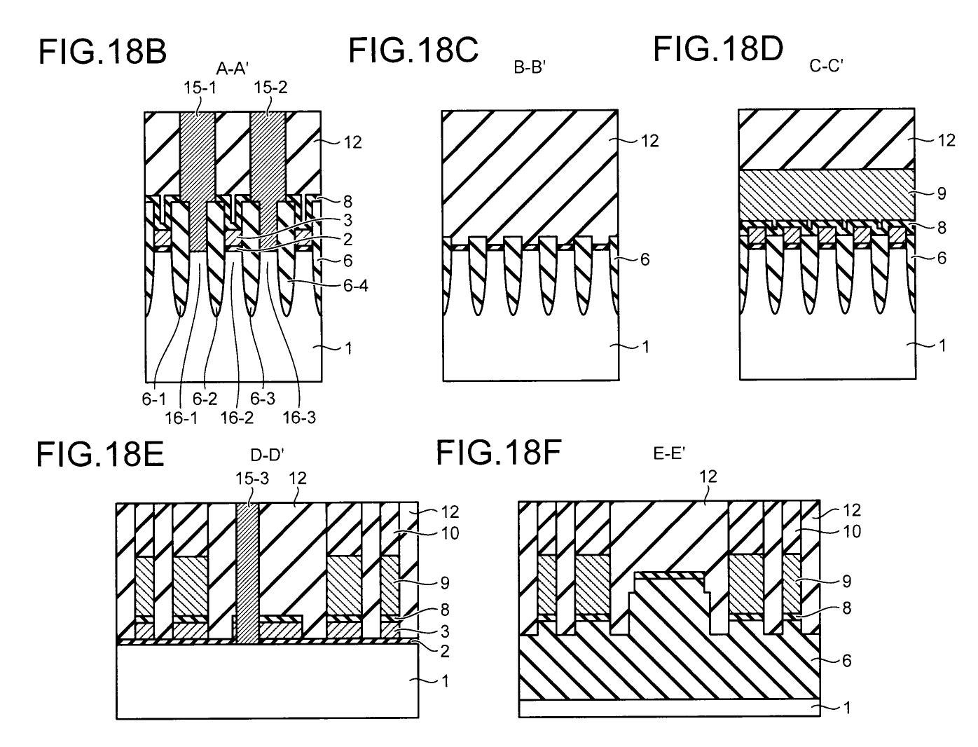

Next, the SiN film 4 of the hardmask is removed by wet etching in phosphoric acid aqueous solution. Here, in a case where the hardmask is not the SiN film 4 but is a CVD-SiO₂ film, it is removed by etching in hydrofluoric acid solution. A state at this time is shown in FIGS. 6A to 6F. FIG. 6A is a top view, FIG. 6B is a cross-sectional view in the A-A′ direction corresponding to a contact form region shown therein, FIG. 6C is a cross-sectional view in the B-B′ direction corresponding to an inter-word line, FIG. 6D is a cross-sectional view in the C-C′ direction corresponding to a word line, FIG. 6E is a cross-sectional view in the D-D′ direction corresponding to the element region, and FIG. 6F is a cross-sectional view in the E-E′ direction corresponding to the STI. FIGS. 6B, 6C and 6D are cross-sectional views in which the paper perpendicular direction is a bit line direction. In the following, the relationships between FIG. 7A and FIGS. 7B to 7F, to the relationships between FIG. 18A and FIGS. 18B to 18F are similar to the relationships between the top view of FIG. 6A and the cross-sectional views of FIGS. 6B to 6F.

Next, as shown in FIG. 7A and FIGS. 7B to 7F, a photoresist film 7 is applied and processed by a lithography technique to cover the bit-line contact forming region (FIGS. 7A and 7B).

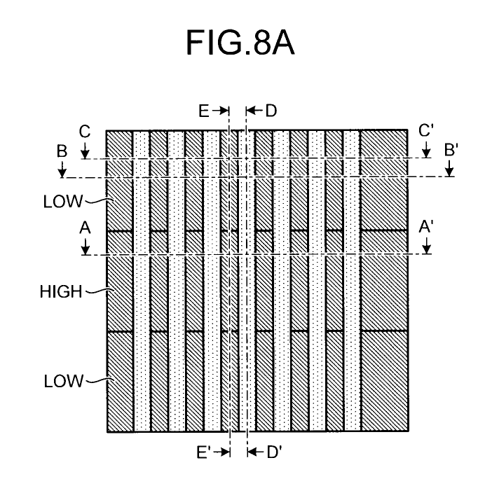

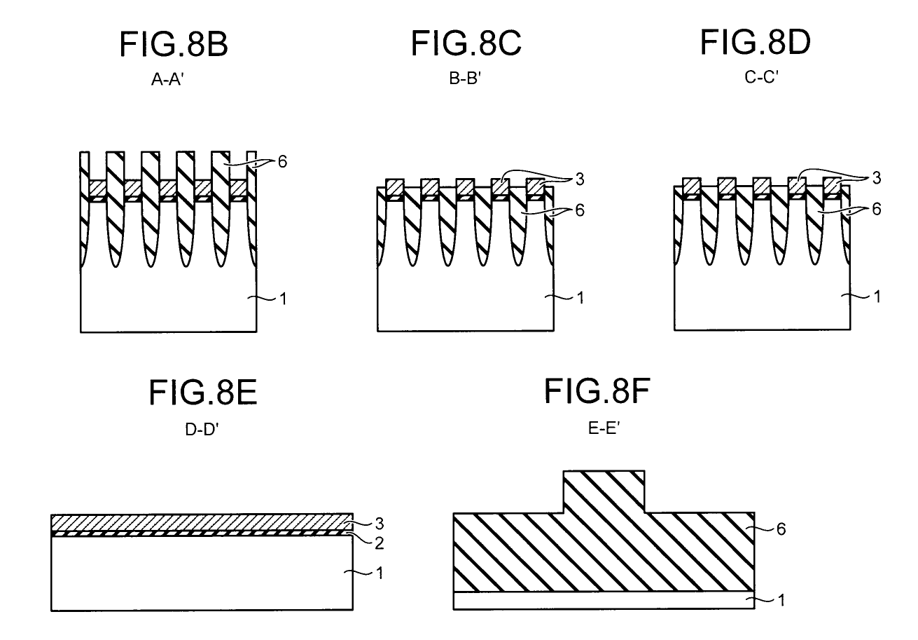

Next, as shown in FIG. 8A and FIGS. 8B to 8F, by RIE or etching in HF solution, the element isolation film 6 that is not covered by the photoresist film 7 is subjected to etching up to the flank of the floating gate 3. That is, the element isolation region 6 different from a region in which the contact form is not planned is subjected to etch-back (FIGS. 8C and 8D). After that, the photoresist film 7 is removed by ashing processing or the like (FIG. 8B).

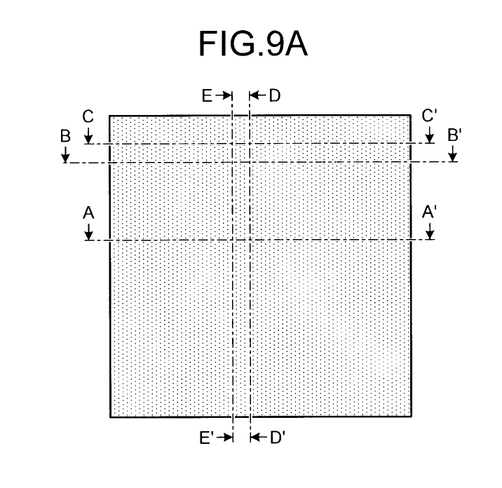

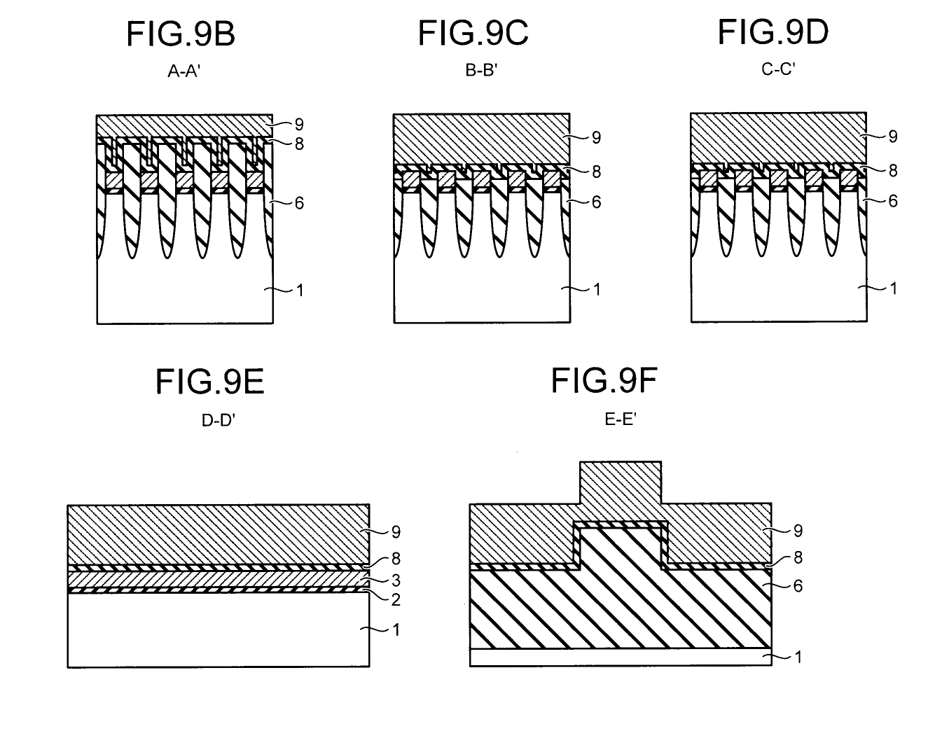

Next, as shown in FIG. 9A and FIGS. 9B to 9F, an interpoly insulating film 8 is formed by a CVD method and a P-doped polycrystalline Si film 9 as a gate electrode is formed thereon. As the interpoly insulating film 8, for example, an ONO film or an Al-type film such as Al₂O₃ is used. Also, for example, as shown in FIGS. 9B to 9F, the interpoly insulating film 8 is formed as a conformal film for a ground such as the floating gate 3 and the element isolation film 6.

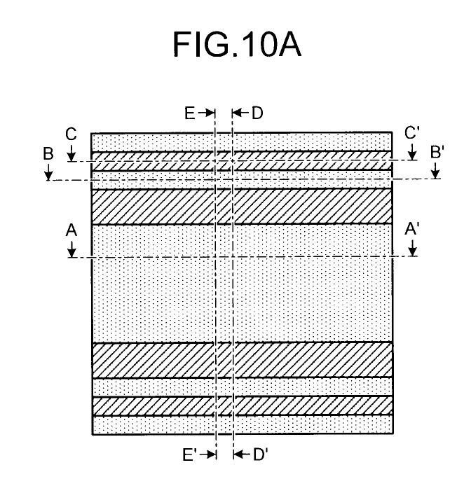

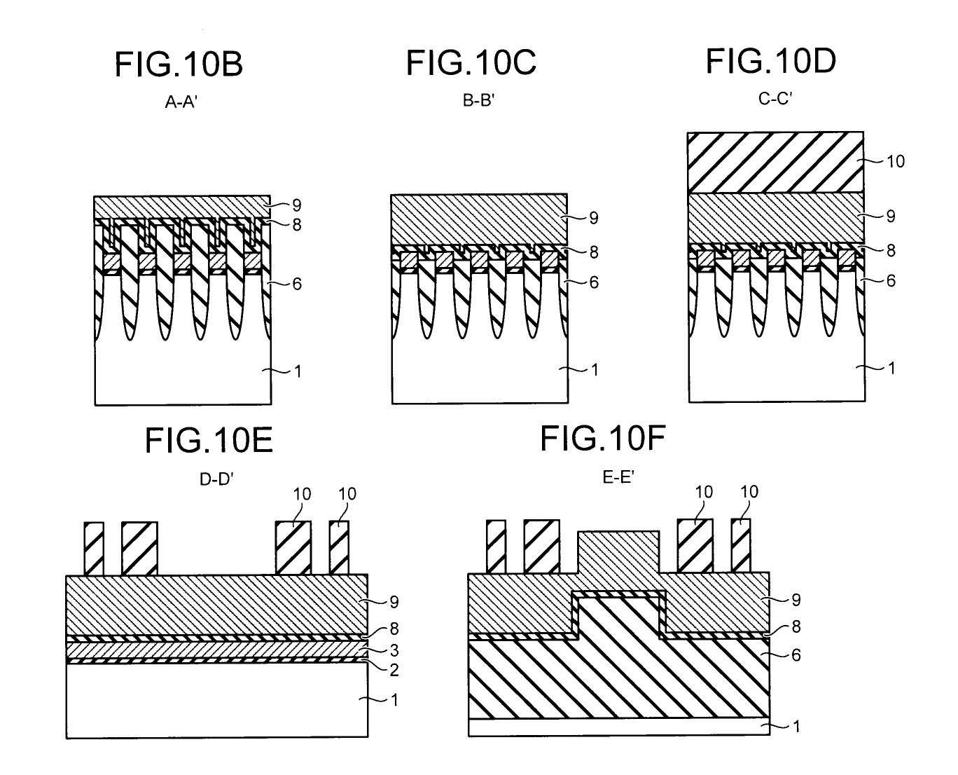

Next, as shown in FIG. 10A and FIGS. 10B to 10F, an SiN film 10 as a mask of RIE is formed by a CVD method and further a photoresist film (not shown) is applied. Here, the SiN film 10 may be an SiO₂ film. Next, the photoresist film is subjected to patterning in a word line (including a select gate) shape by a normal lithography technique and, using the photoresist film as a mask, the SiN film 10 is processed by RIE to remain on a word line to form a hardmask. The photoresist is removed by ashing processing or the like.

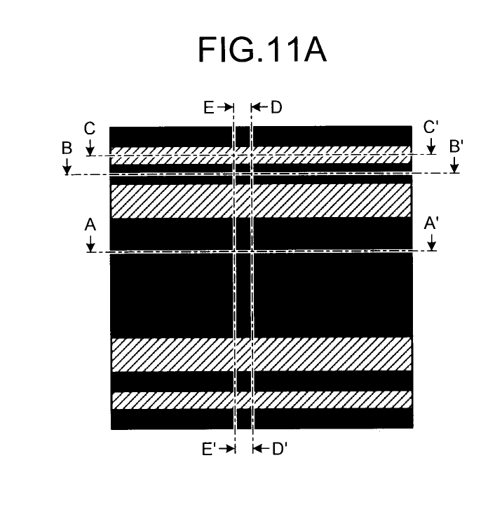

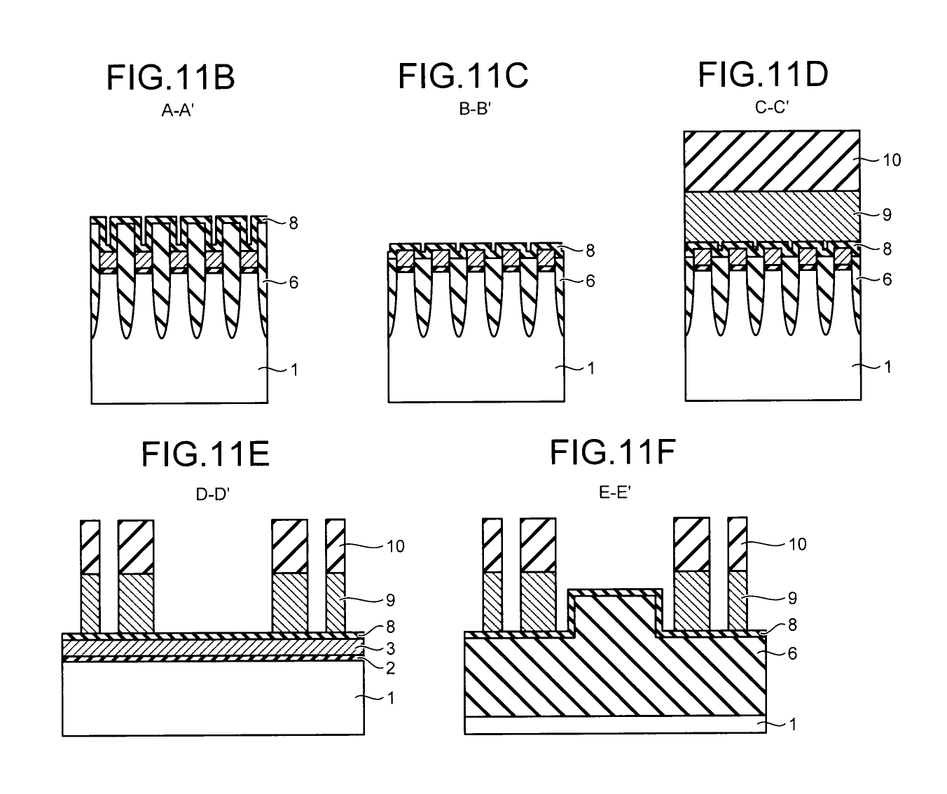

Next, as shown in FIG. 11A and FIGS. 11B to 11F, using the SiN film 10 as a hardmask, the P-doped polycrystalline Si film 9 is processed by RIE.

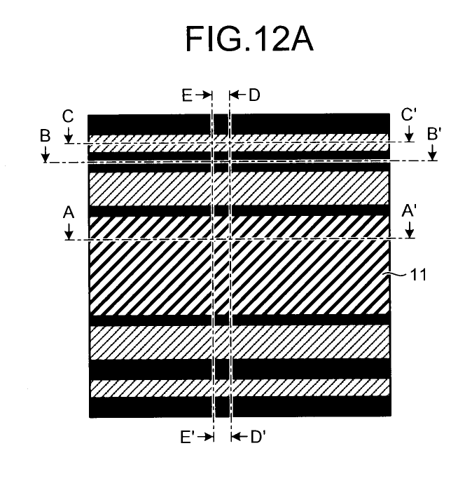

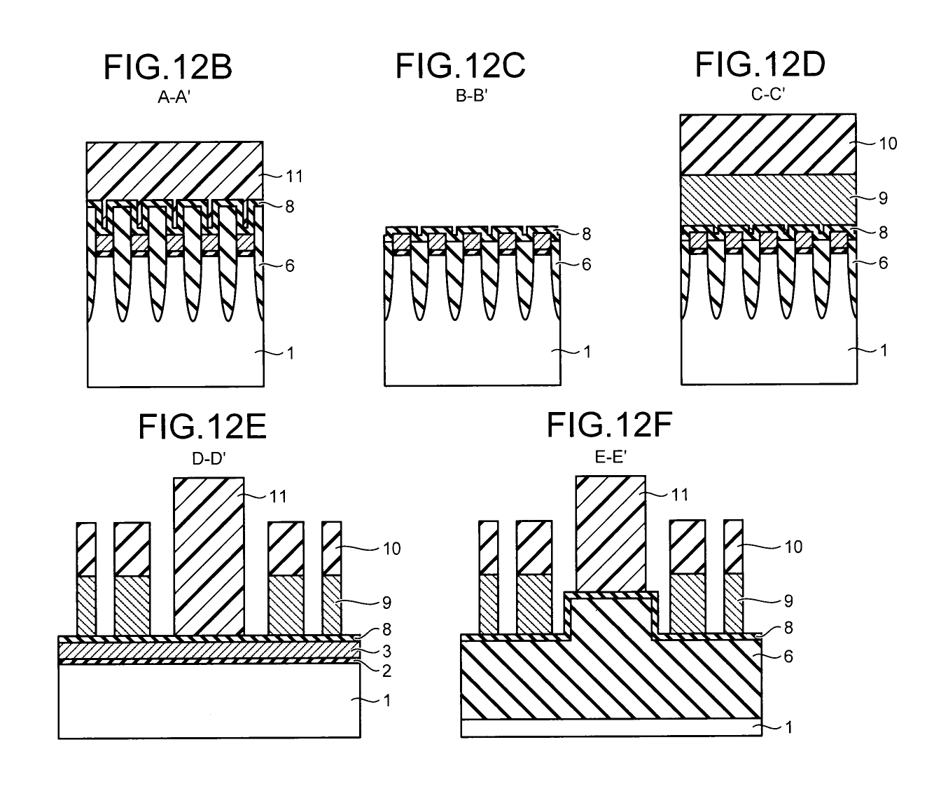

Next, as shown in FIG. 12A and FIGS. 12B to 12F, a photoresist film 11 is applied, and the photoresist film 11 is processed by a normal lithography technique to cover the contact form region with the photoresist film 11.

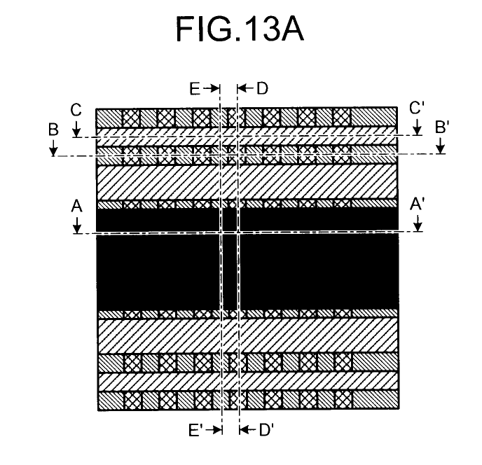

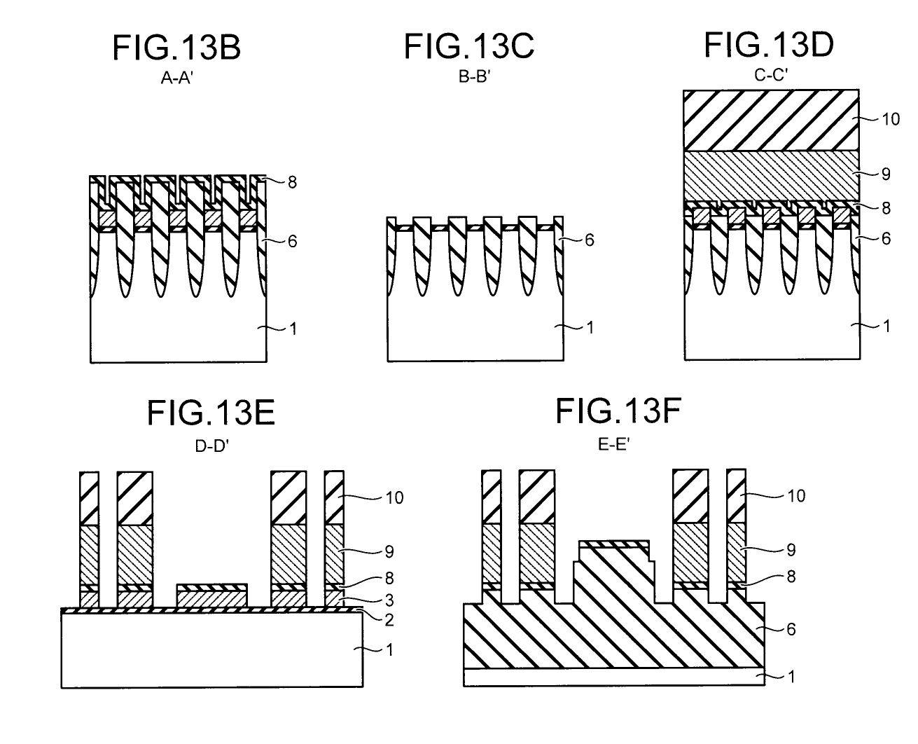

Next, as shown in FIG. 13A and FIGS. 13B to 13F, using the SiN film 10 as a hardmask on the word line and the photoresist film 11 as a mask on the contact form region, the interpoly insulating film 8 and the floating gate layer 3 are processed by RIE. The photoresist 11 is removed by ashing processing or the like.

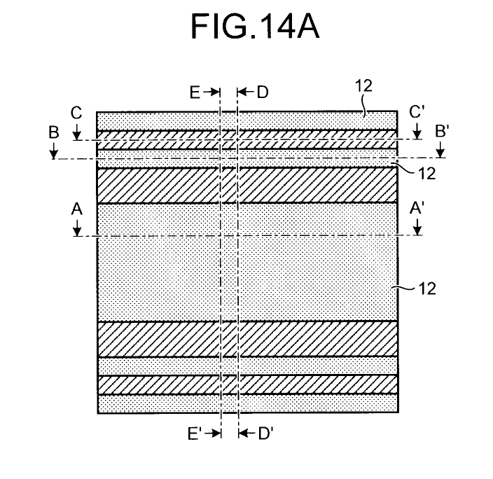

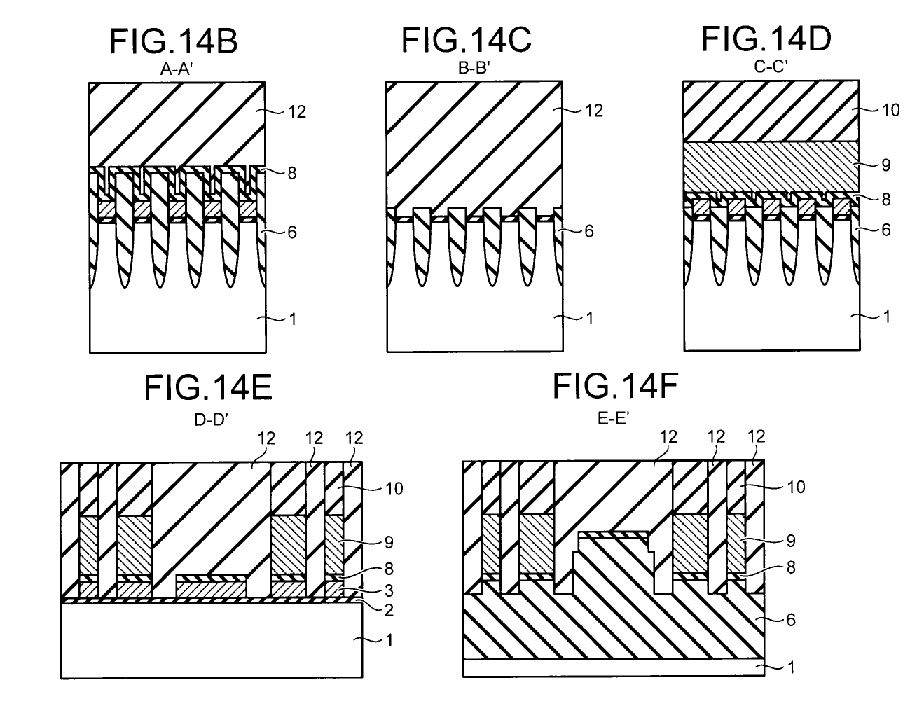

Next, as shown in FIG. 14A and FIGS. 14B to 14F, a silicon oxide film is formed by a CVD method as an interlayer insulating film 12 for the inter-word line to fill the inter-word line. By CMP, the interlayer insulating film 12 is polished and the SiN film 10 is planarized as a stopper film. Here, in addition to the interlayer insulating film 12, another interlayer insulating film may be formed.

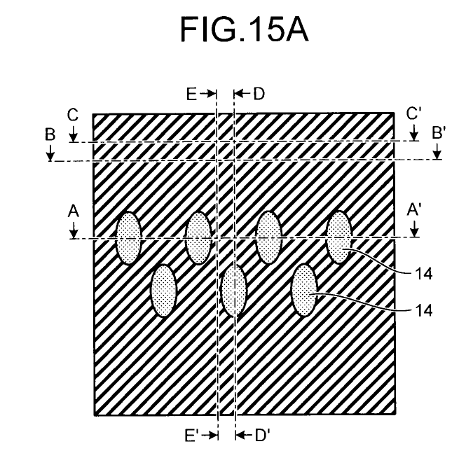

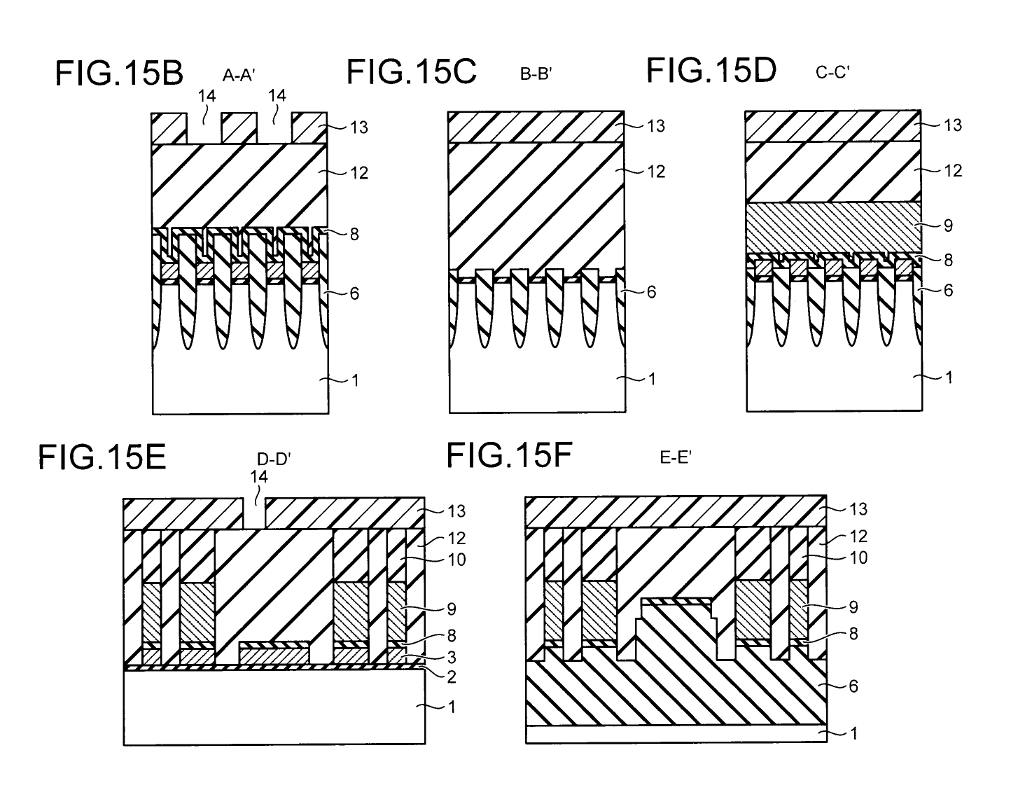

Next, as shown in FIG. 15A and FIGS. 15B to 15F, a photoresist film 13 is applied and processed by a normal lithography technique to form a bit-line contact forming hole pattern 14. At this time, as shown in FIG. 15A, the hole pattern 14 is arranged in a staggered pattern.

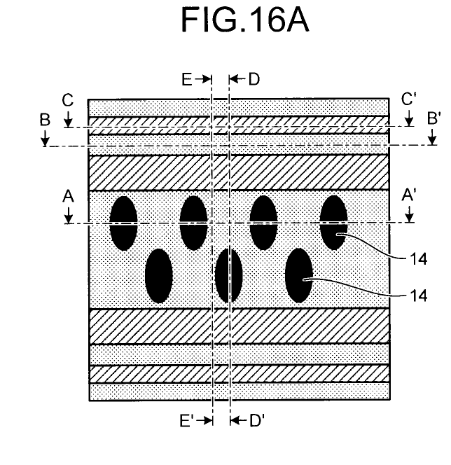

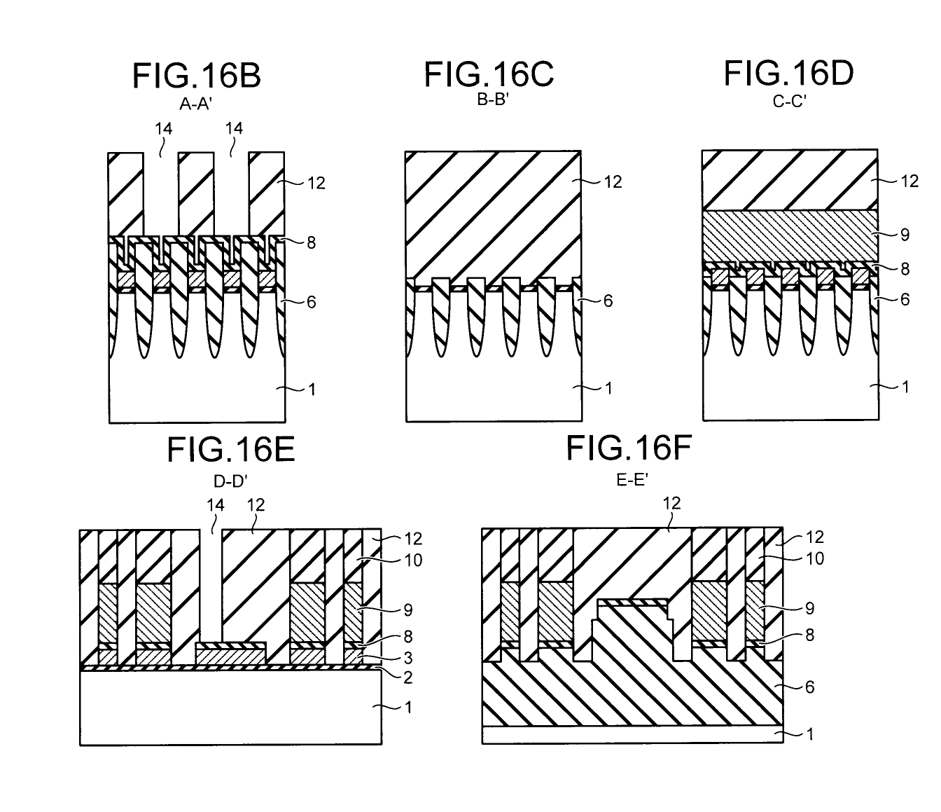

Next, as shown in FIG. 16A and FIGS. 16B to 16F, using the photoresist film 13 as a mask, the hole pattern 14 is processed by RIE for an SiO₂ film of the interlayer insulating film 12. The photoresist film 13 is removed by asking processing or the like. This etching proceeds up to an upper surface of the interpoly insulating film 8 (FIG. 16B and FIG. 16E).

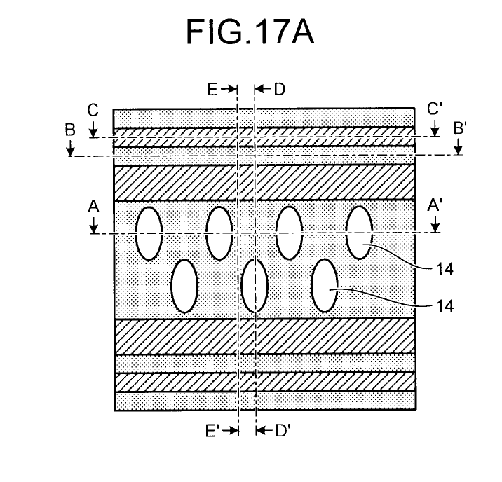

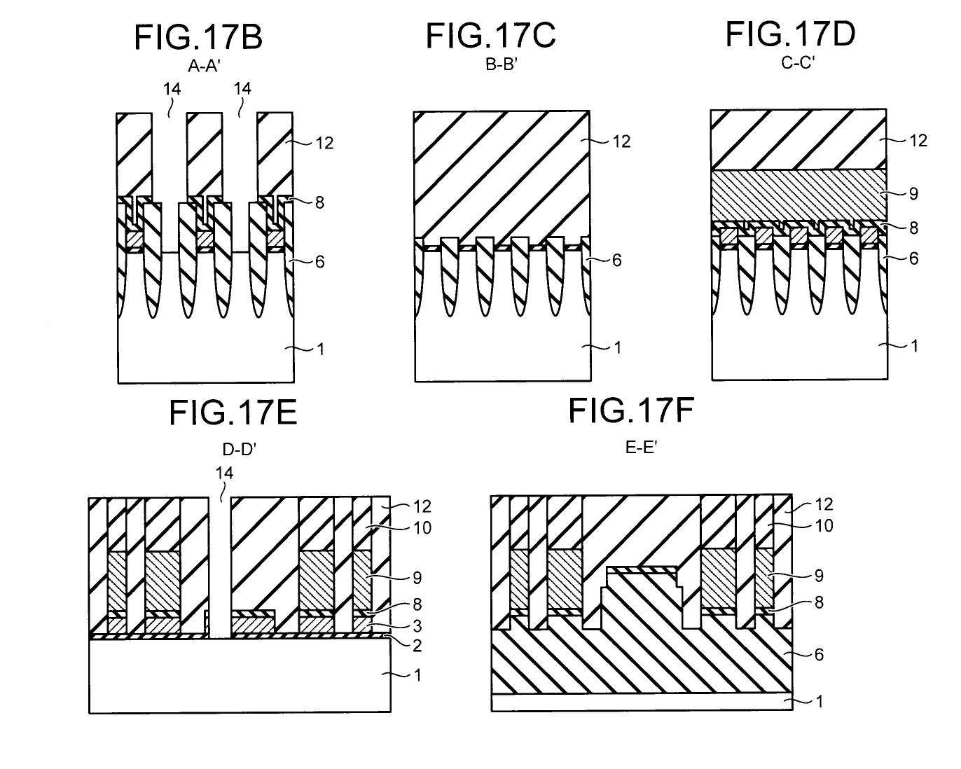

Next, as shown in FIG. 17A and FIGS. 17B to 17F, the floating gate layer 3, the tunnel insulating film 2, and the interpoly insulating film 8 of a bit line contact portion are processed by RIE. When the floating gate layer 3 is processed, it is processed in gas conditions having a selectivity to SiO₂ of the element isolation film 6 such as CDE (Chemical Dry Etching) by a mixed gas of CF₄ and O₂ and RIE (Reactive Ion Etching) by gases including HBr, Cl and F, and etching of the element isolation film 6 is suppressed. Also, depending on a condition, part of the interpoly insulating film 8 may remain on a side wall of the element isolation film 6 to narrow an opening portion between the element isolation films 6 shown in FIG. 17B more or less.

Next, as shown in FIG. 18A and FIGS. 18B to 18F, wiring metals 15-1, 15-2, 15-3 and 15 such as tungsten are formed by a CVD method for the hole pattern 14 of the bit line contact portion to form a bit line contact.

By this means, as shown in FIGS. 18A, 18B and 18E, a nonvolatile semiconductor storage device is provided, including: a first element isolation region 6-1, a second element isolation region 6-2, a third element isolation region 6-3 and a fourth element isolation region 6-4 that are formed on the semiconductor substrate 1, separated in parallel and have the same upper surface height; a first element region 16-1 that is sandwiched between the first element isolation region 6-1 and the second element isolation region 6-2 in a word line direction (or A-A′ direction) and has a lower upper surface height than the first element isolation region 6-1 and the second element isolation region 6-2; a second element region 16-2 that is sandwiched between the second element isolation region 6-2 and the third element isolation region 6-3 in the word line direction and has the same upper surface height as the first element region 16-1; a third element region 16-3 that is sandwiched between the third element isolation region 6-3 and the fourth element isolation region 6-4 in the word line direction and has the same upper surface height as the first element region 16-1; a first bit line contact electrode 15-1 that is formed in a reverse convex shape and in contact with the upper surface of the first element region 16-1, parts of a side surface and the upper surface of the first element isolation region 6-1 that are positioned higher than the upper surface of the first element region 16-1 and face the second element isolation region 6-2, and parts of a side surface and the upper surface of the second element isolation region 6-2 that are positioned higher than the upper surface of the first element region 16-1 and face the first element isolation region 6-1; a second bit line contact electrode 15-2 that is positioned in the word line direction with respect to the first bit line contact electrode 15-1, formed in a reverse convex shape and in contact with the upper surface of the third element region 16-3, parts of a side surface and the upper surface of the third element isolation region 6-3 that are positioned higher than the upper surface of the third element region 16-3 and face the fourth element isolation region 6-4, and parts of a side surface and the upper surface of the fourth element isolation region 6-4 that are positioned higher than the upper surface of the third element region 16-3 and face the third element isolation region 6-3; the tunnel insulating film 2 that is positioned in the word line direction with respect to the first bit line contact electrode 15-1 and formed on the second element region 16-2; the floating gate film 3 that is positioned in the word line direction with respect to the first bit line contact electrode 15-1 and formed on the tunnel insulating film 2; and a third bit line contact electrode 15-3 that is not positioned in the word line direction with respect to the first bit line contact electrode 15-1 and is formed in a reverse convex shape and in contact with the upper surface of the second element region 16-2, parts of a side surface and the upper surface of the second element isolation region 6-2 that are positioned higher than the upper surface of the second element region 16-2 and face the third element isolation region 6-3, and parts of a side surface and the upper surface of the third element isolation region 6-3 that are positioned higher than the upper surface of the second element region 16-2 and face the second element isolation region 6-2.

As described above, the present embodiment relates to a nonvolatile semiconductor device using a bit line contact and STI and a manufacture method therefor, where shallow trench isolation “STI” of a bit line contact portion of the nonvolatile semiconductor device is formed higher than an element region and therefore the bit line contact portion formed in a gap has a reverse convex-shaped cross-sectional surface. When processing a floating gate layer at the time of forming a bit line contact hole, by maintaining a selectivity to an element isolation film, it is easily possible to form a reverse convex shape. At the same time, the bit line contact portion is arranged in a staggered pattern, seen from the upper surface. The bit line contact portion is shifted in a plane and arranged by the staggered pattern, and the bottom surface of the bit line contact portion and the upper surface of the element region are in contact with each other in the same width in a region between two element isolation regions, so that it is possible to widen the distance between the bit line contact and an adjacent element region, compared to the related art. By this means, it is possible to relieve an electric field therebetween to prevent breakdown.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a first element isolation region, a second element isolation region, a third element isolation region and a fourth element isolation region that are formed on a semiconductor substrate, extended in a first direction, separated in parallel and have a same upper surface height;
a first element region that is sandwiched between the first element isolation region and the second element isolation region in a second direction perpendicular to the first direction and has an upper surface located in a lower position than an upper surface of the first element isolation region and an upper surface of the second element isolation region;
a second element region that is sandwiched between the second element isolation region and the third element isolation region in the second direction and has a same upper surface height as the first element region;
a third element region that is sandwiched between the third element isolation region and the fourth element isolation region in the second direction and has a same upper surface height as the first element region;
a first bit line contact electrode that is formed in a reverse convex shape and in contact with an upper surface of the first element region, parts of a side surface and the upper surface of the first element isolation region that are positioned higher than the upper surface of the first element region and face the second element isolation region, and parts of a side surface and the upper surface of the second element isolation region that are positioned higher than the upper surface of the first element region and face the first element isolation region;
a second bit line contact electrode that is positioned in the second direction with respect to the first bit line contact electrode, formed in a reverse convex shape and in contact with an upper surface of the third element region, parts of a side surface and an upper surface of the third element isolation region that are positioned higher than the upper surface of the third element region and face the fourth element isolation region, and parts of a side surface and an upper surface of the fourth element isolation region that are positioned higher than the upper surface of the third element region and face the third element isolation region; and
a third bit line contact electrode that is positioned in a different direction from the second direction with respect to the first bit line contact electrode, formed in a reverse convex shape and in contact with an upper surface of the second element region, parts of a side surface and the upper surface of the second element isolation region that are positioned higher than the upper surface of the second element region and face the third element isolation region, and parts of a side surface and the upper surface of the third element isolation region that are positioned higher than the upper surface of the second element region and face the second element isolation region.

2. The nonvolatile semiconductor storage device according to claim 1, further comprising:
a tunnel insulating film that is positioned in the second direction with respect to the first bit line contact electrode and formed on the second element region;
a floating gate film that is positioned in the second direction with respect to the first bit line contact electrode and formed on the tunnel insulating film; and
an interpoly insulating film that is positioned in the second direction with respect to the first bit line contact electrode and formed on the floating gate film.

3. The nonvolatile semiconductor storage device according to claim 2, wherein the interpoly insulating film is in contact with the first bit line contact electrode, the second element isolation region, the third element isolation region and the second bit line contact electrode.

4. The nonvolatile semiconductor storage device according to claim 1, wherein the first bit line contact electrode, the second bit line contact electrode, and the third bit line contact electrode are located in a staggered pattern in a cross-sectional view by a plane including the first direction and the second direction.

5. The nonvolatile semiconductor storage device according to claim 2, wherein cross-sectional surfaces including surfaces of the first bit line contact electrode, the second bit line contact electrode and the third bit line contact electrode in the first direction and the second direction form a staggered pattern.

6. The nonvolatile semiconductor storage device according to claim 3, wherein cross-sectional surfaces including surfaces of the first bit line contact electrode, the second bit line contact electrode and the third bit line contact electrode in the first direction and the second direction form a staggered pattern.

7. The nonvolatile semiconductor storage device according to claim 2, wherein the interpoly insulating film is an ONO film or an Al-type film.

8. The nonvolatile semiconductor storage device according to claim 3, wherein the interpoly insulating film is an ONO film or an Al-type film.

9. The nonvolatile semiconductor storage device according to claim 5, wherein the interpoly insulating film is an ONO film or an Al-type film.

10. The nonvolatile semiconductor storage device according to claim 6, wherein the interpoly insulating film is an ONO film or an Al-type film.

11. A manufacture method for a nonvolatile semiconductor storage device, comprising:
forming a tunnel insulating film, a floating gate layer and a hardmask layer in order on a semiconductor substrate;
forming a hardmask by processing the hardmask layer to remain on an element region;
etching the floating gate layer, the tunnel insulating film and the semiconductor substrate in order, except for a region just below the hardmask, to form a trench;
filling the trench with an element isolation film;
planarizing the element isolation film using the hardmask as a stopper;
removing the hardmask;
covering a bit line contact forming region with a resist;
etching an upper surface of the element isolation film that is not covered with the resist such that the upper surface is located between an upper surface and a lower surface of the floating gate layer;
removing the resist;
forming an interpoly insulating film and a control gate layer on the element isolation film and the floating gate layer;
forming a second hardmask in a word line shape on the control gate layer;
etching the control gate layer using the second hardmask as a mask;
covering the interpoly insulating film on the bit line contact forming region with a second resist after etching the control gate layer;
etching the interpoly insulating film and the floating gate layer using the second hardmask and the second resist as a mask and removing the second resist;
forming an interlayer insulating film on the interpoly insulating film on the bit line contact forming region;
forming a contact hole having a greater radius than a width in a word line direction of the floating gate layer immediately below the interlayer insulating film, in the interlayer insulating film on the bit line contact forming region;
forming the contact hole in a reverse convex shape by etching the interpoly insulating film, the floating gate layer and the tunnel insulating film below the contact hole in a condition that a selectivity of the element isolation film with respect to the floating gate layer is high; and
filling the contact hole formed in a reverse convex shape with an electric conductor.

12. The manufacture method for the nonvolatile semiconductor storage device according to claim 11, wherein forming the contact hole in a reverse convex shape is performed by etching on a gas condition having a high selectivity of the element isolation film with respect to the floating gate layer.

13. The manufacture method for the nonvolatile semiconductor storage device according to claim 11, wherein the interpoly insulating film is formed in a conformal manner on the element isolation film and the floating gate layer.

14. The manufacture method for the nonvolatile semiconductor storage device according to claim 12, wherein the interpoly insulating film is formed in a conformal manner on the element isolation film and the floating gate layer.

15. The manufacture method for the nonvolatile semiconductor storage device according to claim 11, wherein, in forming the contact hole, a plurality of the contact holes form a staggered pattern in a cross-sectional surface perpendicular to a extending direction of the contact hole.

16. The manufacture method for the nonvolatile semiconductor storage device according to claim 12, wherein, in forming the contact hole, a plurality of the contact holes form a staggered pattern in a cross-sectional surface perpendicular to a drawing direction of the contact hole.

17. The manufacture method for the nonvolatile semiconductor storage device according to claim 13, wherein, in forming the contact hole, a plurality of the contact holes form a staggered pattern in a cross-sectional surface perpendicular to a drawing direction of the contact hole.

18. The manufacture method for the nonvolatile semiconductor storage device according to claim 14, wherein, in forming the contact hole, a plurality of the contact holes form a staggered pattern in a cross-sectional surface perpendicular to a drawing direction of the contact hole.
